(19) United States
(12) Patent Application Publication
(10) Pub. No.: US 2011/0031516 A1
(43) Pub. Date: Feb. 10, 2011

(54) LED WITH SILICONE LAYER AND LAMINATED REMOTE PHOSPHOR LAYER

(75) Inventors: Grigoriy Basin, San Francisco, CA (US); Paul S. Martin, Singapore (SG)

Correspondence Address: PHILIPS INTELLECTUAL PROPERTY & STANDARDS, P.O. BOX 3001, BRIARCLIFF MANOR, NY, 10510, US

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/537,909

(22) Filed: Aug. 7, 2009

(51) Int. Cl. H01L 33/00; H01L 21/56

(52) U.S. Cl. 257/98; 438/26; 257/E21.502; 257/E33.061

(57) ABSTRACT

A method for fabricating a light emitting device is described where an array of flip-chip light emitting diode (LED) dies are mounted on a submount wafer. Over each of the LED dies is simultaneously molded a hemispherical first silicone layer. A preformed flexible phosphor layer, comprising phosphor powder infused in silicone, is laminated over the first silicone layer to conform to the outer surface of the hemispherical first silicone layer. A silicone lens is then molded over the phosphor layer. By preforming the phosphor layer, the phosphor layer may be made to very tight tolerances and tested. By separating the phosphor layer from the LED die by a molded hemispherical silicone layer, color vs. viewing angle is constant, and the phosphor is not degraded by heat. The flexible phosphor layer may comprise a plurality of different phosphor layers and may comprise a reflector or other layers.

### FIELD OF THE INVENTION

This invention relates to light emitting diodes (LEDs) with an overlying layer of phosphor to wavelength convert the LED emission and, in particular, to a technique of laminating a remote phosphor layer over the LED to achieve more precise color control and more uniform color vs. viewing angle.

### BACKGROUND

Prior art FIG. 1 illustrates a conventional flip chip LED die 10 mounted on a portion of a submount wafer 12. In a flip-chip, both the n and p contacts are formed on the same side of the LED die.

The LED die 10 is formed of semiconductor epitaxial layers, including an n-layer 14, an active layer 15, and a p-layer 16, grown on a growth substrate, such as a sapphire substrate. The growth substrate has been removed in FIG. 1 by laser lift-off, etching, grinding, or by other techniques. In one example, the epitaxial layers are GaN based, and the active layer 15 emits blue light. LED dies that emit UV light are also applicable to the present invention.

A metal electrode 18 electrically contacts the p-layer 16, and a metal electrode 20 electrically contacts the n-layer 14. In one example, the electrodes 18 and 20 are gold pads that are ultrasonically welded to anode and cathode metal pads 22 and 24 on a ceramic submount wafer 12. The submount wafer 12 has conductive vias 24 leading to bottom metal pads 26 and 28 for bonding to a printed circuit board. Many LEDs are mounted on the submount wafer 12 and will be later singulated to form individual LEDs/submounts.

Further details of LEDs can be found in the assignee's U.S. Pat. Nos. 6,649,440 and 6,274,399, and U.S. Patent Publications US 2006/0281203 A1 and 2005/0269582 A1, all incorporated herein by reference.

To produce white light using the blue LED die 10, it is well known to deposit a YAG phosphor, or red and green phosphors, directly over the die 10 by, for example, spraying or spin-coating the phosphor in a binder, electrophoresis, applying the phosphor in a reflective cup, or other means. It is also known to affix a preformed tile of phosphor (e.g., a sintered phosphor powder) on the top of the LED die 10. Such phosphor layers are non-remote since they directly contact the surface of the semiconductor die 10. Blue light leaking through the phosphor, combined with the phosphor light, produces white light. Problems with such non-remote phosphors include: 1) the photon density is very high for high power LEDs and saturates the phosphor; 2) the LED is very hot and phosphors may react to the heat to cause darkening of the polymer binder layer (e.g., silicone) in which the phosphor particles are imbedded; 3) due to the various angles of blue light rays passing through different thicknesses of phosphors (a normal blue light ray passing through the least thickness), the color varies with viewing angle; and 4) it is difficult to create very uniform phosphor layer thicknesses and densities.

It is also known to infuse phosphor powder in a silicone binder and mold the silicone over the LED die to form a lens. However, mold tolerances affect the thickness and alignment of the phosphor, which affect the overall color and color vs. viewing angle. Mold tolerances are generally 30-50 microns, and the desired phosphor thickness is only on the order of 100 microns, so it is difficult to achieve a ±50K target correlated color temperature (CCT) for a white LED over a certain viewing angle specified by a customer.

Blue LED dies formed using the same process produce slightly different dominant wavelengths, and LEDs are sometimes binned according to their dominant wavelength. So if the same phosphor layer were applied to each blue LED die, the overall color temperature would be different for each bin of LED die. If white LEDs need to be matched, such as for backlights, such LEDs would have to come from the same bin. This effectively reduces yield for certain stringent applications.

Additionally, reproducibility of the phosphor layer is difficult using the prior art processes.

What is needed is a technique to create a phosphor-converted LED that does not suffer from the above-described drawbacks.

### SUMMARY

To achieve a more precise phosphor layer for use with a blue or UV LED die to create white light (or another color), a remote phosphor layer is used. The remote phosphor layer is spaced from the LED die so, compared to a phosphor that is formed directly on the LED die surface, there is a lower photon density and the phosphor experiences a lower temperature. The photon density is lower since the LED die light is spread out over a larger area before impinging on the remote phosphor layer.

To achieve greater precision in the phosphor layer thickness, density, and wavelength conversion characteristics, the phosphor layer is a preformed, tested layer comprising phosphor powder infused in a silicone binder. A sheet of such a phosphor layer is formed to have a well-controlled thickness and phosphor density. The sheet is tested, such as by energizing it with blue light, to determine its dominant wavelength output. Phosphor sheets having different characteristics are then matched up with binned blue LED dies. In this way, a target white light CCT can be achieved using blue LEDs from different bins.

To space the preformed phosphor layer from the LED die, a silicone layer is first molded over the LED die to encapsulate the die. In one embodiment, this first molded silicone layer has a substantially hemispherical shape. The matched phosphor sheet is laminated over the silicone layer using a vacuum, and the application of heat adheres the phosphor sheet to the silicone layer. Any typical imprecision in the mold or alignment (e.g., 30-50 microns) when forming the silicone layer does not significantly affect the white light CCT since the phosphor layer is remote and will also have a hemispherical shape.

A second silicone layer is molded over the phosphor layer to protect the phosphor layer and serve as a lens. In one embodiment, the second silicon layer is substantially hemispherical so that the white LED outputs a Lambertian pattern. The shape of the second silicone lens may be formed to create any type of emission pattern

The above process is performed simultaneously on an array of LED dies mounted on a submount wafer. The array of dies may be from a single bin. The phosphor layer may be a single sheet that spans the entire wafer. The wafer is then singulated to separate out the white light LEDs/submounts.

In one embodiment, the phosphor layer contains a YAG phosphor (yellow-green). In another embodiment, the phosphor layer contains mixed red and green phosphors. In another embodiment, the phosphor layer comprises multiple layers, such as a layer of red and a separate layer of YAG to produce a warm white color. The process can be used to make any color light using any type of phosphor.

### BRIEF DESCRIPTION OF THE DRAWINGS

FIG. 1 is a cross-sectional view of a prior art blue or UV flip-chip LED die, mounted on a submount.

FIG. 2 illustrates a simplified submount wafer populated by an array of LED dies, such as 500-4000 LEDs, where all LED dies on the wafer are simultaneously processed.

FIG. 3 illustrates the submount wafer being brought against a mold for forming a first silicone layer for encapsulating the LED dies and spacing a phosphor layer from the LED dies.

FIG. 4 illustrates the LED dies immersed in the silicone filling the mold indentions.

FIG. 5 illustrates a preformed, thin, and flexible phosphor layer being laminated over the molded silicone layer using a vacuum and heat, such that the phosphor layer conforms to the outer surface of the silicone layer.

FIG. 6 illustrates a phosphor sheet with a layer of red phosphor and a layer of a YAG phosphor (or a green phosphor).

FIG. 7 illustrates a multi-layer phosphor sheet where the top layer is formed having microlenses.

FIG. 8 illustrates a multi-layer phosphor sheet where there is a reflective layer on the bottom that passes blue light but reflects red, green, and yellow light.

FIG. 9 illustrates a multi-layer phosphor sheet where the top surface is formed to have varying thicknesses to match characteristics of the individual LED dies.

FIG. 10 illustrates a phosphor layer with an overlying pigmented layer.

FIG. 11 illustrates a white light LED after undergoing the processes described herein.

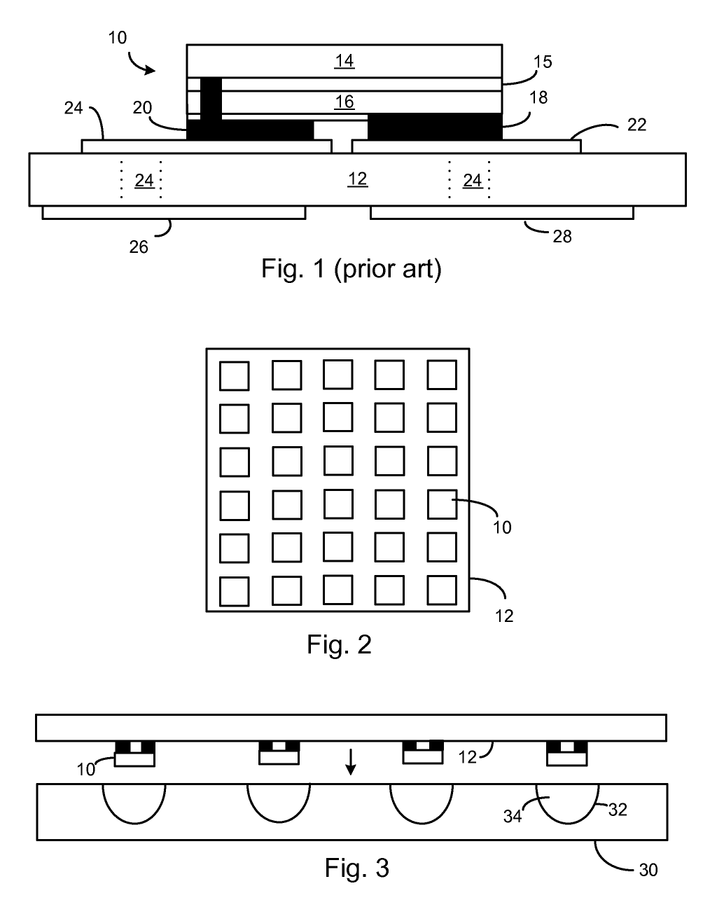

Elements that are the same or equivalent are labeled with the same numeral.

### DETAILED DESCRIPTION

FIG. 2 is a simplified illustration of a submount wafer 12 on which is mounted an array of LED dies 10. There may be 500-4000 LEDs on a single submount wafer 12. All LEDs on the wafer 12 will be processed simultaneously using the method described below.

A first silicone layer is molded over the LED dies 10 to encapsulate the dies 10 as follows.

FIG. 3 illustrates a portion of the submount wafer 12 and LED dies 10 being positioned over a mold 30 having cavities 32 filled with liquid silicone 34, or softened silicone 34, or powered silicone 34, or silicone in tablets. If the silicone 34 is not dispensed in liquid or softened form, the mold 30 is heated to soften the silicone 34. The submount wafer 12 is brought against the mold 30, as shown in FIG. 4, so that the LED dies 10 are immersed in the silicone 34 in each cavity 32. The wafer 12 and mold 30 are pressed together to force the silicone 34 to fill all voids. A perimeter seal allows the pressure to be high while allowing all air to escape as the silicone 34 fills the voids. A vacuum may also be pulled between the wafer 12 and the mold 30 using a vacuum source around the seal.

The mold 30 is then heated to cure the silicone 34, depending on the type of silicone 34 used. If the original silicone 34 was a solid (e.g., a powder or tablets) at room temperature, the mold 30 is cooled to harden the silicone 34. Alternatively, a transparent mold may be used and the silicone 34 may be cured with UV light.

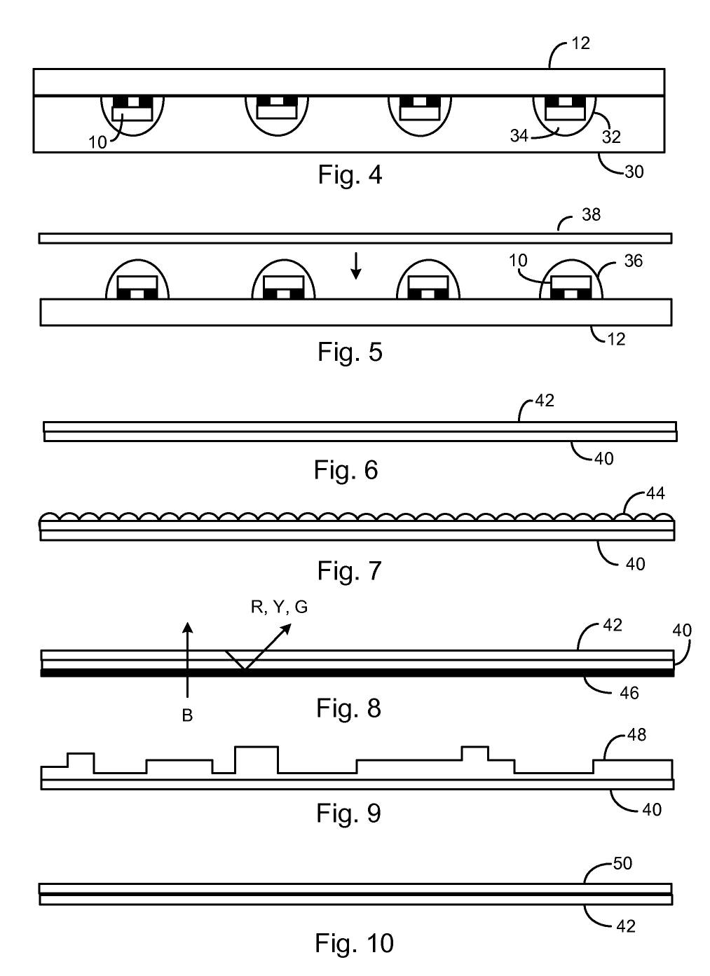

The mold 30 is then removed from the wafer 12, resulting in the structure of FIG. 5, where the resulting silicone layer 36 encapsulates each LED die 10. In the embodiment shown, the silicone layer 36 is formed to have a substantially hemispherical shape. The thickness of the silicone layer 36 is not critical since the LED light expands in a Lambertian pattern through the transparent silicone layer 36.

The wafer 12 may then be subjected to a post-cure temperature of about 250° C. to additionally harden the silicone layer 36, depending on the type of silicone 34 used. Materials other than silicone may be used such as an epoxy molding compound in powder form or another suitable polymer.

The silicone layer 36 may also be formed using injection molding, where the wafer 12 and mold are brought together, a liquid silicone is pressure-injected into the mold through inlets, and a vacuum is created. Small channels between the mold cavities allow the silicone to fill all the cavities. The silicone is then cured by heating, and the mold is separated from the wafer 12.

The silicone layer 36 serves to separate a uniform phosphor layer from the LED die, as described below.

FIG. 5 illustrates a preformed phosphor layer 38 being laminated to the surface of the wafer 12 and to the silicone layer 36. The phosphor layer 38 may be the same size as the wafer 12. The phosphor layer 38 is formed of a suitable phosphor powder, such as YAG, red, or green phosphor, or any combination of phosphors, to achieve the target color emission. To create the phosphor layer 38, the phosphor powder is mixed with silicone to achieve a target density, and the phosphor layer 38 is formed to have a target thickness. The desired thickness may be obtaining by spinning the mixture on a flat surface or molding the phosphor layer.

After the phosphor layer 38 is cured, the phosphor layer 38 may be tested by energizing the phosphor layer 38 using a blue light source and measuring the light emission. Since blue LEDs generally emit slightly different dominant wavelengths, the blue LEDs may be tested prior to being mounted on the submount wafer 12, and the LEDs are binned according to their dominant wavelengths. Preformed phosphor layers of varying thicknesses or phosphor densities are then matched up with LEDs from particular bins so that the resulting color emissions may all be the same target white point (or CCT). If all LED dies on the submount wafer 12 are from the same bin and the phosphor layer 38 was previously matched to that bin, the color emission will be a target CCT.

In one embodiment, the phosphor layer 38 is on the order of a few hundred microns thick and highly flexible.

As shown in FIG. 5, the matched phosphor layer 38 is placed over the wafer 12, and a vacuum is drawn between the phosphor layer 38 and the wafer 12 to remove all air. This will conformally coat the silicone layer 36 and wafer 12. The structure is then heated to adhere the silicone in the phosphor layer 38 to the silicone layer 36.

By laminating a preformed phosphor layer rather than forming the phosphor over the LED die, uniform phosphor thickness and density are guaranteed. It is very easy to create a uniform phosphor sheet. By spacing the phosphor layer 38 from the LED die 10 using the silicone layer 36, the photon density at the phosphor layer 38 is reduced, there are no thermal degradation problems with the phosphor, the refractive index of the silicone layer 36 can be tailored to increase the extraction efficiency, and there are no mold tolerances that affect the phosphor layer 38 performance. Since no mold misalignment affects the phosphor layer, there is improved color uniformity. The color vs. viewing angle is consistent since the blue LED light passes through equal thicknesses of the phosphor layer 38 at all angles.

Another advantage of the preformed laminated phosphor layer 38 is that the phosphor layer may be formed of multiple layers, each layer being customized and precisely formed. FIGS. 6-10 illustrate some multi-layered phosphor layers that can be laminated onto the wafer 12. In the preferred embodiment, the multi-layer sheet is preformed, due to the ease of laminating the layers together, and the sheet is tested and then laminated as a single sheet to the wafer 12. Alternatively, the multiple layers may be individually laminated onto the wafer 12.

FIG. 6 illustrates a red phosphor layer 40 with an overlying YAG phosphor layer 42. The red phosphor layer 40 is customized to create a warmer white, since the yellow-green YAG phosphor tends to create a harsh white. A green phosphor may be used instead of YAG. Any number of phosphor layers may be formed to create the desired color characteristics. In one embodiment, a UV LED die is used and one of the layers is a blue phosphor layer. The multiple phosphor layers may be separately formed and laminated together using heat and pressure and/or a vacuum.

FIG. 7 illustrates that the top phosphor layer 44 may be molded to have tiny lenses (or other optical elements) over its surface to reduce TIR or to achieve increase light scattering or other optical effects.

FIG. 8 illustrates that one of the laminated layers may be a chromatic reflector 46 that allows blue light to pass but reflects longer wavelength light. In this way, the light produced by the phosphors is not absorbed by the LED die 10 but is always reflected upward.

FIG. 9 illustrates that the top phosphor layer 48 may be molded to have different thicknesses to be matched with individual blue LED dies 10 on the wafer 12 to achieve the same target CCT for each LED.

FIG. 10 illustrates that a phosphor layer 42 may be laminated with a non-phosphor optical layer 50 that may be a pigmented color filter, a light scattering layer (e.g., silicone containing particles of TiO₂), or other type of layer.

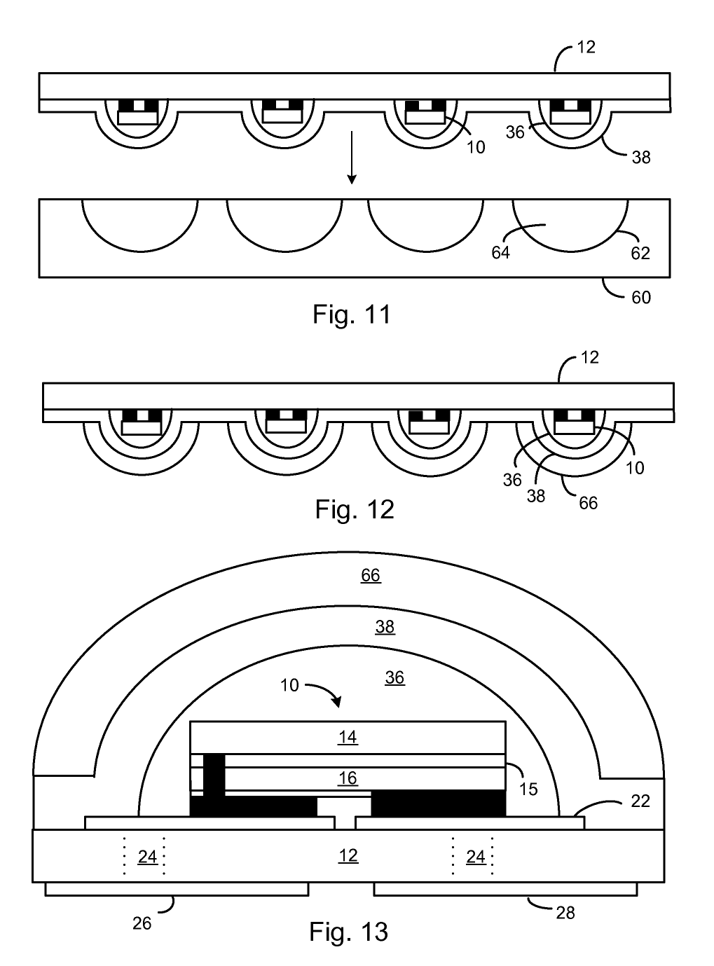

FIG. 11 illustrates the wafer 12 with the laminated phosphor layer 38 being brought against a mold 60 in order to form a silicone lens over the LEDs. This will protect the laminated phosphor layer 38, create any desired emission pattern, and increase light extraction by tailoring the refractive index of the silicone and the shape of the lens.

In FIG. 11, the mold 60 contains cavities 62 filled with silicone 64 for forming a hemispherical lens 66 (FIG. 12). The molding process may be the same as describe with respect to FIG. 3. The lens 66 may instead be a side-emitting lens or any other type of lens. The lens 66 may even have phosphor powder (e.g., red phosphor) in it to shift the output color temperature.

FIG. 12 shows the wafer 12 removed from the mold 60 after curing.

In one embodiment, the first silicone layer 38 has a refractive index of 1.4, and the lens 66 has an index of 1.5 to reduce the percentage of blue photons that are internally reflected. The mold for the outer lens 66 may create a roughened outer surface to increase light extraction efficiency.

By using lamination of the preformed phosphor layer 38, mold tolerances do not affect the color emission or color vs. viewing angle. Since many LEDs from the same bin are processed simultaneously on a wafer scale, and the phosphor layer 38 is laminated as a large sheet, the LEDs generate a target CCT to very tight tolerances (less than 50K), and processing is relatively easy.

The submount wafer 12 is then singulated to form individual LEDs/submounts, where one such LED is shown in FIG. 13. Note that the phosphor layer 38 continues to the edges of the singulated submount.

In this disclosure, the term “submount wafer” is intended to mean a support for an array of LED dies, where electrical contacts on the wafer are bonded to electrodes on the LED dies, and the wafer is later singulated to form one or more LEDs on a single submount, where the submount has electrodes that are to be connected to a power supply.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

1. A method for fabricating a light emitting device comprising:
providing a plurality of light emitting diode (LED) dies on a submount wafer;
molding a first silicone layer over each LED die on the wafer;
forming a flexible phosphor layer separately from the wafer;
laminating the phosphor layer over the wafer such that the phosphor layer directly contacts and conforms to an outer surface of the first silicone layer, the phosphor layer wavelength-converting light emitted from the LED dies; and
molding a second silicone layer over the phosphor layer.

2. The method of claim 1 wherein the second silicone layer comprises a lens.

3. The method of claim 1 wherein the first silicone layer is substantially hemispherical.

4. The method of claim 1 wherein the phosphor layer comprises phosphor powder infused in silicone.

5. The method of claim 1 wherein the first silicone layer has a first index of refraction and the second silicone layer has a second index of refraction higher than the first index of refraction.

6. The method of claim 1 wherein the phosphor layer has an area approximately the same as or larger than an area of the wafer.

7. The method of claim 1 wherein the phosphor layer has a substantially uniform thickness.

8. The method of claim 1 wherein the phosphor layer comprises multiple layers, wherein at least two of the layers contain different phosphors.

9. The method of claim 1 wherein the phosphor layer comprises multiple layers, wherein at least one of the layers comprises a reflector.

10. The method of claim 1 wherein the phosphor layer is molded to have optical features.

11. The method of claim 1 wherein providing a plurality of LED dies on the submount wafer comprises bonding electrodes on the submount wafer to corresponding electrodes of the plurality of LED dies.

12. The method of claim 1 further comprising singulating the submount wafer to separate LED dies mounted on their respective submount portions, after the step of molding the second silicone layer.

13. A light emitting device comprising:
a light emitting diode (LED) die mounted on a submount;
a first silicone layer coating the LED die, wherein the first silicone layer has a substantially hemispherical shape over the LED die;
a phosphor layer laminated over the first silicone layer to conform to an outer surface of the first silicone layer, the phosphor layer extending beyond the LED die over the submount, the phosphor layer comprising phosphor powder infused in silicone; and
a second silicone layer molded over the phosphor layer.

14. The device of claim 13 wherein the phosphor layer comprises a plurality of layers of different phosphors infused in silicone.

15. The device of claim 13 wherein the phosphor layer has a substantially uniform thickness.
